(19) United States
(12) Patent Application Publication
(10) Pub. No.: US 2007/0120117 A1
(43) Pub. Date: May 31, 2007

(54) SEMICONDUCTOR ELEMENT AND METHOD OF MANUFACTURING THE SAME

(75) Inventors: Isao Takasu, Kawasaki-Shi (JP); Isao Amemiya, Tokyo (JP); Shuichi Uchikoga, Yokohama-Shi (JP); Rei Hasegawa, Yokohama-Shi (JP); Hideyuki Nakao, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/531,098

(22) Filed: Sep. 12, 2006

(30) Foreign Application Priority Data
Nov. 29, 2005 (JP) 2005-344396

(51) Int. Cl. H01L 29/08

(52) U.S. Cl. 257/40

(57) ABSTRACT

The present invention provides a semiconductor element having a semiconductor layer that has high carrier mobility and is easy to form. This semiconductor element includes a semiconductor layer made of TeI₄, which has a clustering structure.

### CROSS-REFERENCE TO RELATED APPLICATION

This application is based upon and claims the benefit of priority from prior Japanese Patent Application No. 2005-344396 filed on Nov. 29, 2005 in Japan, the entire contents of which are incorporated herein by reference.

### BACKGROUND OF THE INVENTION

1. Field of the Invention

The present invention relates to a semiconductor element and a method of manufacturing the semiconductor element.

2. Related Art

A thin-film field-effect transistor (TFT) that is conventionally used in a flat panel display such as a liquid crystal display normally uses amorphous silicon or polycrystalline silicon for a semiconductor layer.

In recent years, along with the development of organic materials, TFTs having semiconductor layers formed with organic semiconductors made of organic materials such as polythiophene and pentacene have been developed. Organic semiconductors differ from silicon semiconductors and many other compound semiconductors in being soluble with an organic solvent or the like. By applying a solution in which an organic semiconductor is solved to a substrate, a semiconductor layer can be readily formed. Therefore, organic semiconductors are regarded as the key to the new industrial field of semiconductor device processing through printing.

It has been reported that a TFT having a semiconductor layer formed with pentacene as an organic semiconductor material, for example, exhibits the carrier mobility of 1 cm²/(V·sec) or higher, which is as high as the carrier mobility of amorphous silicon (see Y. Y. Lin, D. J. Gundlach, S. F. Nelson, T. N. Jackson, IEEE Electron Device Lett. Vol. 18, pp. 606-608 (1997), for example). Carrier mobility is often used as the indicator of organic semiconductor performance.

JP-A 2005-48091 (KOKAI) discloses a technique of forming a derivative that is soluble with an organic solvent by introducing a side chain such as an alkoxyl group or the like into a conductive polymer such as polyacetylene, polypyrrole, polythiophene, or polyaniline.

JP-A 2002-198539 (KOKAI) discloses the use of an organic-inorganic hybrid semiconductor as the semiconductor layer of a TFT. JP-A 2003-309308 (KOKAI) discloses a technique of forming a semiconductor layer of a TFT by melting an organic-inorganic hybrid semiconductor in a solid state without a solvent.

However, low-molecular semiconductors that reportedly have high carrier mobility are known to have low solubility with organic solvents. For example, pentacene, which is disclosed in “Y. Y. Lin, D. J. Gundlach, S. F. Nelson, T. N. Jackson, IEEE Electron Device Lett. Vol. 18, pp. 606-608 (1997)”, is said to have very low solubility with conventional organic solvents. To solve pentacene with an organic solvent or the like, it is necessary to heat the solvent to a high temperature and increase the solubility. Also, the derivative disclosed in JP-A 2005-48091 (KOKAI) has lower carrier mobility than any of low molecular semiconductors that generally exhibit high carrier mobility.

Even if semiconductor layers are produced with the above mentioned organic materials, the molecular order greatly varies among the semiconductor layers, depending on the temperature, the material of the substrate, and the drying condition at the time of the formation of the semiconductor layers through solution coating or the like. This is because an organic material normally has high anisotropy in its molecular structure. The variation in the molecular order causes a wide variation in the performances of semiconductor elements. Furthermore, many organic materials are easily oxidized and become unstable when brought into contact with the air at the time of melting. During the thin film formation through the process of printing or the like, it is necessary to carry out the process in a nitrogen atmosphere in which oxygen does not exist.

Meanwhile, each of the organic-inorganic hybrid semiconductors disclosed in JP-A 2002-198539 (KOKAI) and JP-A 2003-309308 (KOKAI) has higher carrier mobility than an organic semiconductor, containing a highly conductive inorganic material. However, each of the organic-inorganic hybrid semiconductors disclosed in JP-A 2002-198539 (KOKAI) and JP-A 2003-309308 (KOKAI) is formed with an insulative organic material and a highly conductive inorganic material. Therefore, at the time of semiconductor formation, the carrier mobility might change, depending on the scattering of the highly conductive inorganic material in the insulative organic material. For example, in a case where a semiconductor layer formed with an organic-inorganic hybrid semiconductor has a laminated structure including an organic layer and an inorganic layer, anisotropy might develop, as current flows in a certain direction in the semiconductor layer but does not flow in any other direction. As a result, the organic layer puts restrictions on electron movement, and limitations on carrier mobility. Also, because of the anisotropy, a defective structure might be found in the interface, and limitations are put on carrier mobility.

Furthermore, the organic-inorganic hybrid semiconductor disclosed in JP-A 2003-309308 (KOKAI) is not solved with a solvent, but is melted to form the semiconductor layer of a TFT. Therefore, by this melting method, the formation of each semiconductor layer is more difficult than in the case where a semiconductor layer is formed through coating.

### SUMMARY OF THE INVENTION

A semiconductor element according to a first aspect of the present invention includes: a semiconductor layer that contains TeI₄ having a clustering structure.

A method of manufacturing a semiconductor element according to a second aspect of the present invention includes: solving TeI₄ with an organic solvent; and applying a solution containing the TeI₄ solved with the organic solvent to a substrate to form a semiconductor layer containing the TeI₄.

### BRIEF DESCRIPTION OF THE DRAWINGS

FIG. 1 is a schematic cross-sectional view showing a semiconductor element as an embodiment according to the present invention;

FIG. 2 is a schematic cross-sectional view showing a semiconductor element as an embodiment according to the present invention;

FIG. 3 is a schematic cross-sectional view showing a semiconductor element as an embodiment according to the present invention;

FIG. 4 is a schematic cross-sectional view showing a semiconductor element as an embodiment according to the present invention;

FIG. 5 is a schematic cross-sectional view showing a semiconductor element as an embodiment according to the present invention;

FIG. 6 is a diagram for explaining a shift in the intramolecular electron distribution (electronic polarization);

FIG. 7A is a diagram showing the chemical formula of benzene;

FIG. 7B is a diagram showing the free electron distribution in benzene, which is the basic skeleton;

FIG. 8A is a diagram showing the chemical formula of pentacene;

FIG. 8B is a diagram showing the free electron distribution in pentacene;

FIG. 9 is a diagram for explaining the problems with a fused-ring case;

FIG. 10 is a diagram showing a clustering structure (TeI₄)₄ in single crystals of Tel₄;

FIG. 11 is a diagram showing the X-ray diffraction pattern in a TeI₄ film;

FIG. 12 is a diagram showing the X-ray diffraction pattern in a TeI₄ single crystal;

FIG. 13 is a diagram showing the raman spectrum of a TeI₄ film;

FIG. 14 is a diagram showing the FET characteristics of a TeI₄ film;

FIG. 15 is a diagram showing a clustering structure (TeI₄)ₙ in a thin film of TeI₄; and

FIG. 16 is a diagram for explaining the intensive intermolecular force between clusters.

### DESCRIPTION OF THE PREFERRED EMBODIMENTS

The following is a description of embodiments of the present invention, with reference to the accompanying drawings. In those drawings, same or like portions are denoted by same or like reference numerals. Since the drawings show merely schematic views, the relationship between the thickness and the two-dimensional size, and the ratio among the thicknesses of the layers are different from those in reality. Therefore, the particular thicknesses and sizes in the description below should be considered to be merely examples. Of course, there are different portions in the size relationship and ratios between the drawings.

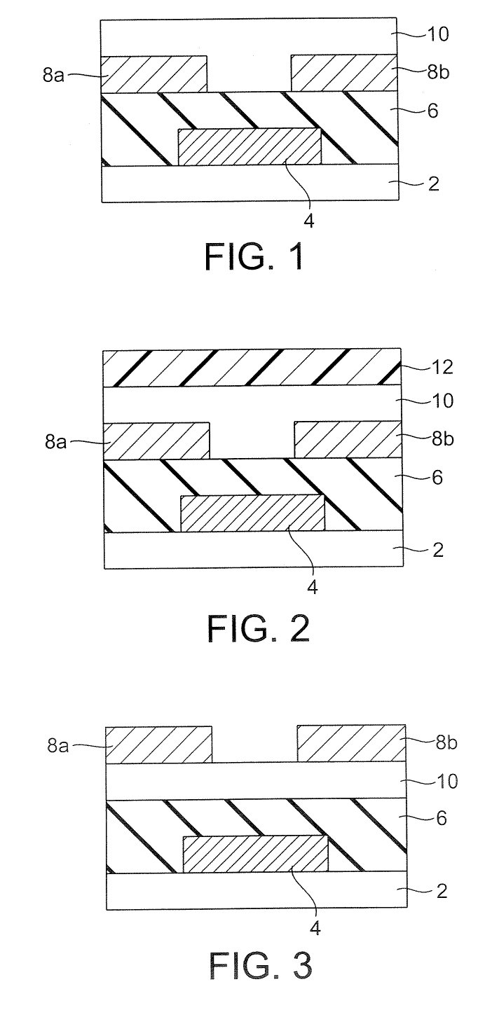

FIGS. 1 to 5 are schematic cross-sectional views of a semiconductor element as an embodiment according to the present invention.

The semiconductor element of this embodiment is a thin-film field-effect transistor (hereinafter referred to as “TFT”), which is of a bottom contact type, for example. More specifically, the semiconductor element of this embodiment includes a substrate 2, a gate electrode 4 placed on the substrate 2, a gate insulating layer 6 placed on the gate electrode 4, a source electrode 8a and a drain electrode 8b placed on the gate insulating layer 6, and a semiconductor layer (an active layer) 10 placed on the gate insulating layer 6, the source electrode 8a, and the drain electrode 8b, as shown in FIG. 1.

The semiconductor element illustrated in FIG. 1 is manufactured in the following manner. First, the substrate 2 is prepared, and the gate electrode 4 is formed on the substrate 2. The gate insulating film 6 is formed so as to cover the gate electrode 4. The source electrode 8a and the drain electrode 8b are formed at a distance from each other on the gate insulating film 6. The active layer 10 is formed so as to cover the source electrode 8a, the drain electrode 8b, and the gate insulating film 6.

As shown in FIG. 2, a sealing layer 12 may be formed on the active layer 10.

The semiconductor element of this embodiment may be a TFT of a top contact type. More specifically, such a semiconductor element includes a substrate 2, a gate electrode 4 placed on the substrate 2, a gate insulating layer 6 placed on the gate electrode 4, an active layer 10 placed on the gate insulating layer 6, and a source electrode 8a and a drain electrode 8b placed on the active layer 10, as shown in FIG. 3.

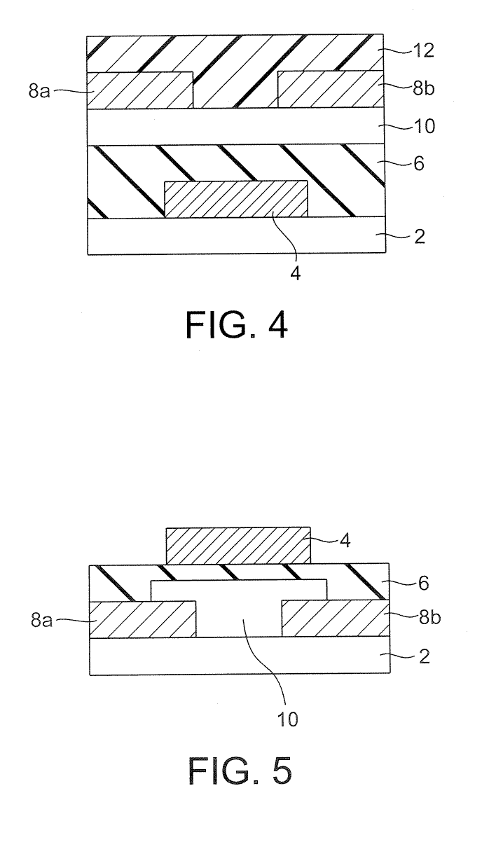

The semiconductor element illustrated in FIG. 3 is manufactured in the following manner. First, the substrate 2 is prepared, and the gate electrode 4 is formed on the substrate 2. The gate insulating film 6 is formed so as to cover the gate electrode 4. The active layer 10 is formed on the gate insulating film 6. The source electrode 8a and the drain electrode 8b are formed on the active layer 10. Thus, the semiconductor element illustrated in FIG. 3 is completed. As shown in FIG. 4, a sealing layer 12 may be provided so as to cover the source electrode 8a, the drain electrode 8b, and the active layer 10.

The semiconductor element of this embodiment may be a TFT of a top gate type. As shown in FIG. 4, more specifically, such a semiconductor element includes a substrate 2, a source electrode 8a and a drain electrode 8b placed on the substrate 2, an active layer 10 interposed between the source electrode 8a and the drain electrode 8b, a gate insulating film 6 placed so as to cover the active layer 10, the source electrode 8a, and the drain electrode 8b, and a gate electrode 4 placed on the gate insulating film 6.

The semiconductor element illustrated in FIG. 5 is manufactured in the following manner. First, the substrate 2 is prepared, and the source electrode 8a and the drain electrode 8b are formed at a distance from each other on the substrate 2. The active layer 10 is formed between the source electrode 8a and the drain electrode 8b. The gate insulating film 6 is formed so as to cover the active layer 10, the source electrode 8a, and the drain electrode 8b. The gate electrode 4 is formed on the gate insulating film 6.

The substrate 2 may be made of a given material, as long as it is possible to form the gate electrode 4, the source electrode 8a, the drain electrode 8b, and the likes on the substrate 2. For example, the substrate 2 may be a glass substrate, a plastic substrate, a quartz substrate, a silicon substrate, or the like.

The materials for the gate electrode 4, the source electrode 8a, and the drain electrode 8b may be employed metal materials such as gold, silver aluminum, nickel, platinum, and palladium. Compounds may also be employed oxide conductors such as ITO, SnO₂, and ZnO, or organic conductive materials such as polythiophene, polypyrrole, polyaniline, and PEDOT:PSS. Those materials are subjected to RF magnetron sputtering, or the like.

The material for the gate insulating film 6 may be used an oxide film such as SiO₂, or an organic insulating film made of polyvinylphenol, polyimide. Particularly, in a case where an insulative polymer soluble in an organic solvent, such as polyvinylphenol, is employed, the gate insulating film 6 can be formed through a coating process such as an inkjet process or a spin coating process.

The material for the sealing layer 12 may be epoxy resin, parylene, or the like. Also, moisture absorbent is also effectively used.

Next, the material for the semiconductor layer (the active layer) 10 is described.

To eliminate the above described problems with respect to solubility, the molecular order of the film, and the stability in the atmosphere, a molecular halogenated metal compound, more particularly, an iodide metal compound is employed as a soluble semiconductor material for the semiconductor layer 10. This compound is solved with a solvent such as an organic solvent described later, and coating is performed by a process such as an inkjet process, spin coating process and casting process etc, so as to form a TFT.

Examples of molecular halogenated metal compounds include SnI₄, TiI₄, SiI₄, GeI₄, AsI₃, SbI₃, and TeI₄. Here, a “molecular” substance has its aggregation state caused by bonds due to intermolecular force. If the aggregation state is due to ion binding, the substance normally exhibits a low solubility in an organic solvent

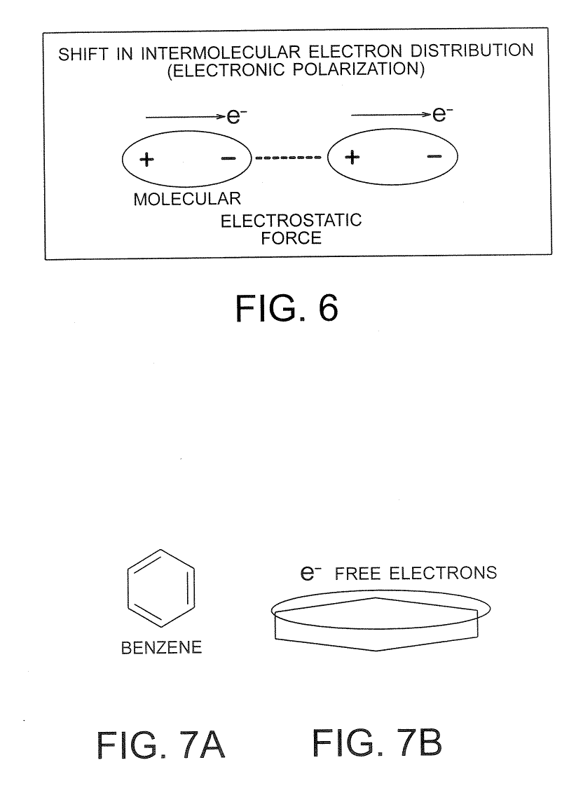

Particularly, in a case of a nonpolar substance, the intermolecular force is generated by the electrostatic attraction in the intramolecular charge distribution due to an electron distribution shift (electronic polarization) caused by a fluctuation in the intramolecular electron distribution, as shown in FIG. 6. Therefore, to increase the molecular force, the intramolecular electronic polarization should be made more prominent.

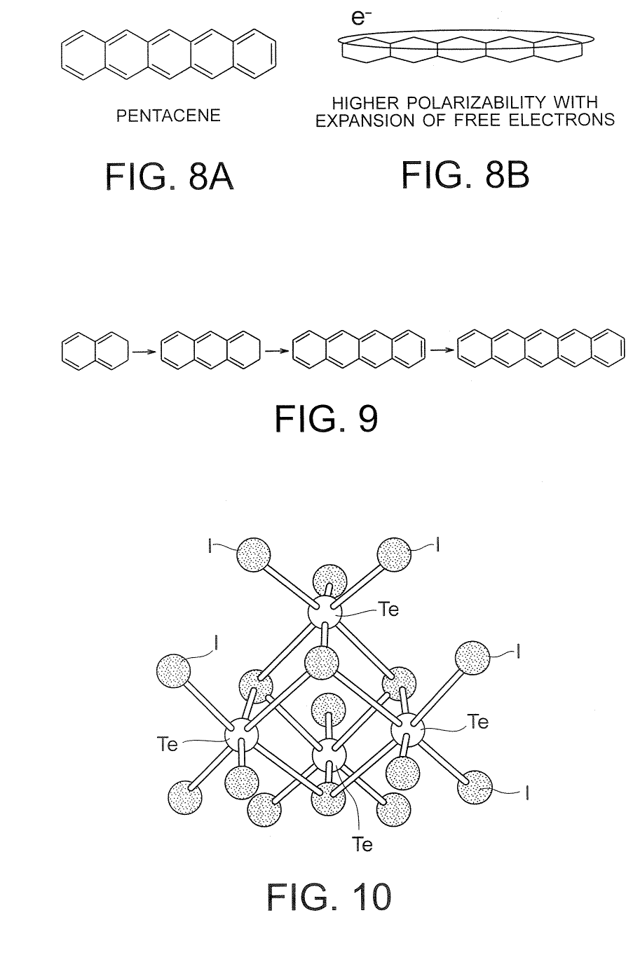

For example, pentacene or the like, which is a fused-ring type aromatic compound to be used as a conventional organic semiconductor for a FET, has free electrons in the pi-conjugated system including double binding, and the free electrons cause the electronic polarization. FIG. 7A shows the chemical formula of benzene, and FIG. 7B shows the free electron distribution in benzene, which is the basic skeleton. As skeletons are linked (fused), the distribution of the free electrons in the pi-conjugated system becomes wider, and more prominent electronic polarization can be caused (FIGS. 8A, 8B). FIG. 8A shows the chemical formula of pentacene, and FIG. 8B shows the free electron distribution in pentacene.

As the number of rings is increased as shown in FIG. 9, the intermolecular force becomes more intensive, and the melting point tends to be higher. At the same time, it is also known that, in terms of the FET characteristics, the carrier mobility becomes higher.

This fact implies that intensive intermolecular force facilitates electron transfer, and increases the carrier mobility. However, it is also known that, as the number of rings is increased, the solubility in a solvent becomes lower. The solubility of pentacene, which is widely used as an organic semiconductor for FETs, is very low with respect to a general solvent at least at room temperature. This proves that it is difficult to fuse an organic semiconductor by increasing the nonlocality of pi-electrons in an aromatic compound.

In another method of increasing the intermolecular force, “elements with large atomic weights” are used. For example, cases where halogen elements are used are described. Halogen elements include fluorine (F₂), chlorine (Cl₂), bromine (Br₂), and iodine (I₂) in the order of molecular weight. At room temperature, these elements are respectively a gas, a liquid, and a solid. In general, an element having a large atomic weight (a larger molecular weight in this example) has a large molecular radius and a large number of electrons. Accordingly, the fluctuation in electron distribution becomes wider, and the electronic polarizability becomes higher. As a result, the intermolecular force increases, and the molecules obviously solidify. In practice, iodine crystals are known as semiconductors having a resistance value of 10⁻⁷/Ωcm at room temperature. This proves that molecules having atoms with large atomic weights can be semiconductors. Iodine is soluble in an organic solvent, and exhibits high electric conduction properties and high solubility.

In a case where an element with a large atomic weight is employed as a p-type semiconductor, the electron donating ability of the molecules should preferably be high so as to maintain charge injection efficiency. Among the halogen elements, fluorine (F), chlorine (Cl), and bromine (Br) have high electronegativity, and accordingly, a compound containing any of them exhibits low electron donating ability. On the other hand, iodine (I) has lower electronegativity and higher electron polarizability than the other halogen elements, as described above. Accordingly, using iodine, the electron donating ability of the molecules might be increased by virtue of a polarizing effect in the solid.

The material of the active layer employed in the semiconductor element of this embodiment should preferably have a clustering structure. For example, in a single crystal, four TeI₄ are associated with one another to form a clustering structure of (TeI₄)₄, as shown in FIG. 10 (see V. B. Krebs and V. Paulat, Acta Cryst. B32, 1470 (1976), for example). A cluster compound is an aggregate formed by binding atoms or molecules affected by various factors, or is a general term for a compound having clusters among molecules. Clusters are classified into: 1) aggregates formed by van der Waals binding; 2) metal clusters; and 3) inorganic compound clusters (such as alkali halide). The clusters described in this specification is the same as 3) inorganic compound clusters.

Next, the benefits of a clustering structure are described. The specific benefits obtained by forming a clustering structure are as follows.

a) In a cluster, the mobility of carriers (electrons or holes) is high, and accordingly, high carrier mobility can be achieved in the entire film. Since a cluster is formed by interatomic binding including covalent binding, the carrier mobility in a cluster is high. Also, the formation of a large cluster relatively reduces the number of hopping conduction times among the molecules in the film, and accordingly, the carrier mobility becomes higher in the entire film.

b) The intermolecular force may be generated by the permanent dipole moment of molecules, or may be generated by the induced dipole moment due to electron fluctuations in the molecules. It is known that the induced dipole moment greatly depends on the electron polarizability of molecules. Accordingly, the iodide elements are known to have high electron polarizability. Furthermore, when a cluster structure is formed with iodide, the electron polarizability in the molecules becomes even higher, to achieve even larger intermolecular force. The high intermolecular force increases the carrier mobility, and can bring out excellent semiconductor characteristics.

c) In a case where carriers are injected to a semiconductor film of a clustering structure, it is essential to keep the ionization potential of the semiconductor film low, so as to efficiently inject holes. In a case of an element having high electron polarizability, such as iodide, the ionization potential in a solid phase is smaller than the ionization potential in a gas phase, as known with iodide elements or organic molecules containing iodide elements. This is because, in a solid phase, the holes generated by electron extraction are stabilized through polarization of the neighboring electrons. Accordingly, in a cluster structure of this embodiment containing iodide elements, the ionization potential of the film can be made lower, and the hole injection efficiency can be made higher.

Next, the solvent such as an organic solvent to be used for forming the semiconductor layer 10 in the semiconductor element of the present invention is described.

The solvent is not limited to any particular type, as long as it can solve the above described material employed as the semiconductor layer 10, and the semiconductor layer 10 can be formed on a semiconductor substrate or the like through applying the solution. Preferred examples of such solvents include organic solvents such as acetone, amyl acetate, ethanol, propanol, and chloroform. For example, among iodine compounds, TeI₄ can be solved with acetone, amyl acetate, ethanol, or the like.

On the other hand, SnI₄ can be solved with an organic solvent such as chloroform.

An iodide molecular compound might exhibit sublimation. Also an iodide molecular compound should preferably avoid contact with moisture. Therefore, it is desirable to seal off the surface of the semiconductor layer of the semiconductor element from the atmosphere. For example, in each of the TFTs of the bottom contact type and the top contact type shown in FIGS. 1 and 3, part of the semiconductor layer 10 is in contact with the atmosphere. Therefore, it is desirable to cover the semiconductor layer 10 with the sealing layer 12, as shown in FIGS. 2 and 4.

A semiconductor element was actually manufactured with an iodide compound as the semiconductor layer 10, and the characteristics of the semiconductor element were evaluated. First, SnI₄, which reportedly has an electric conduction property, was used as an iodide compound, and the results were examined. It has been reported that the electric conduction of SnI₄ crystals is 10⁻⁹/Ωcm for both single crystals and fine particles. A TFT of a bottom contact type as shown in FIG. 1 was produced with a semiconductor layer of SnI₄, and the characteristics of the TFT were examined. To form the SnI₄ semiconductor layer, the SnI₄ was solved with chloroform, and the obtained solution was applied onto a Si substrate having a gold electrode, followed by drying.

As a result, particulate single crystals were grown between the source electrode and the drain electrode, and a film with a uniform thickness was not formed There, FET characteristics were actually measured. However, the current value was very small, and FET characteristics were not observed at all.

Since the melting point of SnI₄ is 143.5° C., the SnI₄ was heated and melted on the substrate. The SnI₄ was then cooled. The resultant film was examined to detect FET characteristics. As a result, an electric field effect was observed in the current flowing between the source and the drain. However, the characteristics showed that the off current considerably increased with an increase n drain voltage, and the ON current did not exhibit a remarkable value. The current on-off ratio was approximately 2.

Although the SnI₄ has a relatively large molecular weight, the results were undesirable because sufficient intermolecular force was not generated and the electron mobility was insufficient in addition to the problem with film forming ability.

Next, the use of TeI₄ was examined.

First, the properties of TeI₄ are now described. It is known that tellurium tetraiodide forms an assembly (a clustering structure) (TeI₄)₄ in a single crystal. This is because the atomic radius of Te is larger than the atomic radius of Sn or the like, and a multi-coordinate structure can be more readily formed with Te.

Although the crystalline structure of this material has been reported, other studies such as spectrographic studies and property studies have hardly been reported. However, a clustering structure of TeI₄ is a structure formed with tellurium and iodide, which have large atomic weights. Such a clustering structure is considered to have high electron polarizability. Accordingly, large intermolecular force and low ionization potential can be expected with TeI₄. It is possible to use this material for the semiconductor layer of a TFT. Actually, the distance between iodides in a TeI₄ cluster in a single crystal is 3.8 Å to 3.9 Å, which is much shorter than twice the value of the van der Waals radius (the standard intermolecular distance) of iodide (4.3 Å). Thus, generation of large intermolecular force can be confirmed.

Next, TeI₄ film formation is described.

A TFT of a bottom contact type having a semiconductor layer made of TeI₄ was produced as shown in FIG. 1, and the obtained characteristics were examined. To form the semiconductor layer, TeI₄ was solved with acetone, and the obtained solution was applied onto a gate insulating film formed through Si thermal oxidization. The applied material was then dried. In the following, the results obtained through X-ray structure analysis and raman spectroscopy are described.

(X-Ray Structure Analysis)

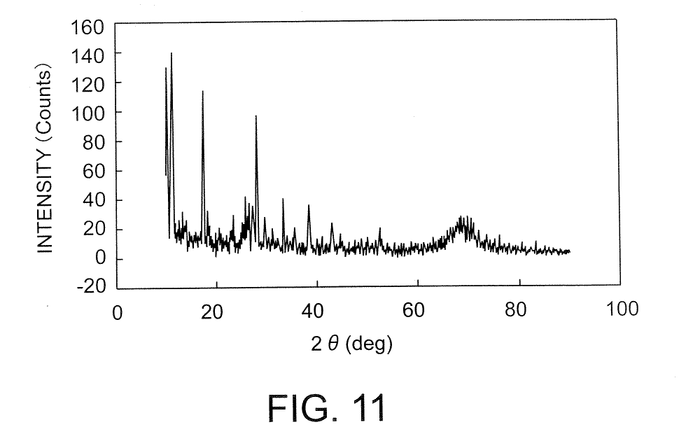

X-ray diffraction measurement was carried out for the TeI₄ formed on the Si thermal oxide film. The results are shown in FIG. 11. The peak in the vicinity of 2θ=70° is due to SiO₂.

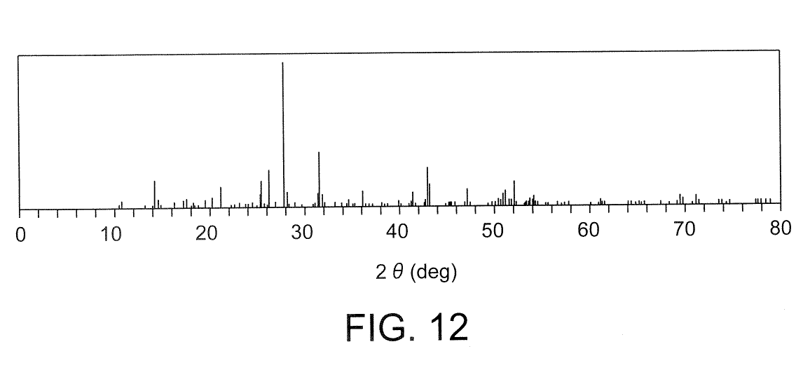

FIG. 12 shows the X-ray diffraction pattern of TeI₄ single crystals according to the ICDD (The International Centre for Diffraction Data) database of the year 2000. Compared with the measurement results of the TeI₄ film, the positions of the peaks of 2θ=28°, 32°, and 43° according to the database are substantially the same as the peaks observed in the TeI₄ film. This implies that the same clustering structure as in the case of a single crystal is formed in the film. However, while there are few intensive peaks at 2θ=20° or less in the single crystal diffraction pattern, strong peaks are observed at 20° or less in the film diffraction pattern. The peaks observed at lower angles mean that there is a longer-period structure. Accordingly, in the case of the TeI₄ film, a larger assembly than (TeI₄)₄ exists.

(Raman Spectroscopic Measurement)

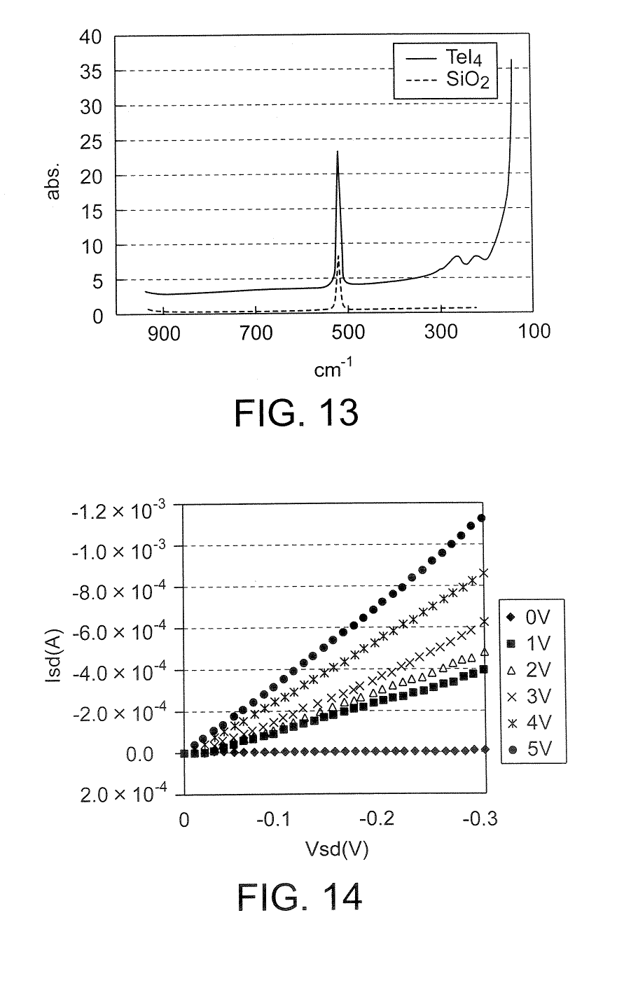

Raman spectroscopic measurement was carried out to study the formation of a clustering structure. The results are shown in FIG. 13. The measurement was carried out on films formed from a TeI₄ acetone solution on a Si substrate having a thermal oxide film.

The scattering intensity was observed at 260 cm⁻¹, 220 cm⁻¹, 160 cm31 1, 160 cm⁻¹ or less. Although no documents on the vibration spectroscopy of TeI₄ have been found, documents on the combination vibration of TeCl₄ and TeBr₄ as the related substances were referred to. According to such documents, TeBr₄ is 184 cm⁻¹ to 192 cm⁻¹ in acetone, TeCl₄ is 248 cm⁻¹ to 264 cm⁻¹ in acetone, and to 360 cm⁻¹ in a solid state. Since a Te—I cluster involves a large atomic weight, the vibration in a Te—I cluster is expected to involve even a smaller wave number than in the case of Te—Br. Contrary to the expectation, the observed wave number was large. This is possibly because high wave-number components are generated in multi-coordinate clusters such as I—Te—I and Te—I—Te. The results indicate the existence of a TeI₄ clustering structure such as (TeI₄)₄.

(FET Measurement)

Next, FET characteristics are described. As a TeI₄ film was formed on a substrate having a gold electrode pattern, a TeI₄ film was also formed between the source electrode and the drain electrode. The FET characteristics of this sample were measured. As a result, an increase in source-drain current upon application of a gate voltage, which is characteristic of a FET, was observed (see FIG. 14). The carrier mobility was approximately 10 cm²/Vs.

As can be seen from the results, a clustering structure having molecules forming a long-period structure is effective in improving the molecular semiconductor characteristics. Inorganic molecules of an atom having a large atomic radius, such as TeI₄, can form a long-period state of assembly, as the number of coordinates in the neighborhood of the atom is variable. Although only a tetramer of TeI₄ exists in a single-crystal state, not only a tetramer but a long-period structure in a larger state of assembly presumably exists in cases of film structures, since an absorption structure with the substrate exists in the vicinity of each interface.

The binding force forming the long-period structure is larger with covalent binding than the intermolecular force that binds organic molecules. Accordingly, the mobility of electrons in a long-period structure (a cluster) is higher. Also, having a long-period structure, a cluster exhibits active electron movement in the covalent binding, as shown in FIG. 16. Between clusters, electron hopping conduction is caused due to strong intermolecular force. As a result, the electron polarizability in each cluster becomes higher, and the intermolecular force between the clusters becomes very large. Accordingly, the electron mobility in the entire film presumably becomes higher. These are structural characteristics that are not observed with an organic semiconductor or an organic-inorganic hybrid semiconductor.

In this specification, a clustering structure is a state of assembly of molecules, so is a long-period structure. One clustering structure can be regarded as a gigantic molecule. As the electron polarizability in each cluster is high, extremely large intermolecular force is generated between clusters. Accordingly, as in the example of organic molecules, the carrier mobility becomes higher as the intermolecular force becomes larger.

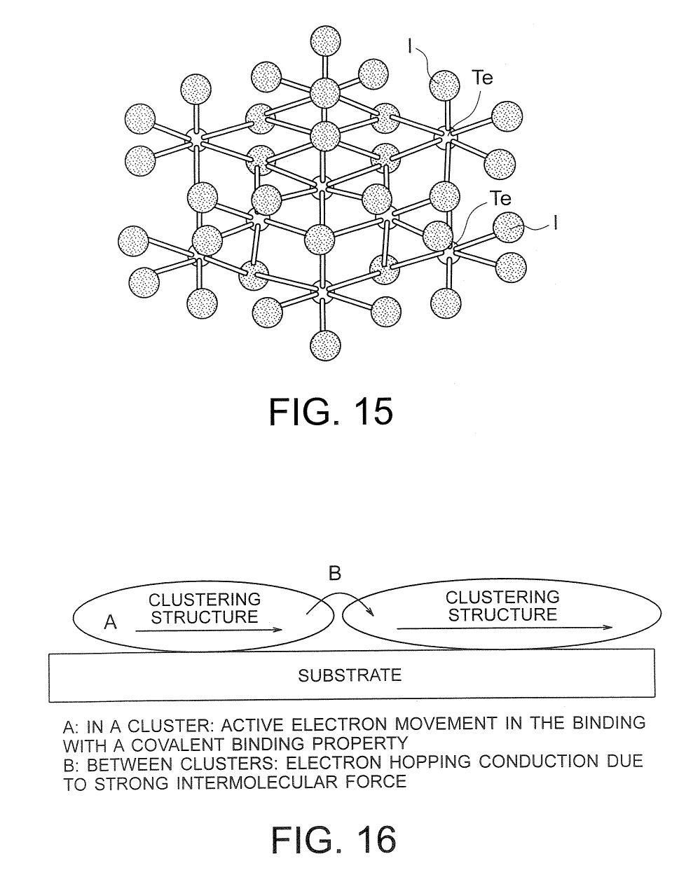

For example, Te₄I₁₆ (=(TeI₄)₄) having the structure shown in FIG. 10 has a state of assembly with the Te—I binding having covalent binding properties. The electrons in this cluster can easily move, as the state of assembly is formed with firmer binding than the intermolecular force. Accordingly, if a larger structure (such as the cluster shown in FIG. 15, (TeI₄)ₙ (n>4)) is formed, the mobility of electrons in the entire film should become higher.

A film structure including such a clustering structure contributes to improvement of characteristics as the semiconductor layer in a TFT of this embodiment, and can be used as a semiconductor material having FET characteristics.

A TeI₄ film should preferably be formed with 100% TeI₄. However, when TeI₄ is solved with an organic solvent such as acetone, and the obtained solution is applied and dried, it is difficult to form a film with 100% TeI₄ by vaporizing all the organic solvent. There is not a problem in terms of characteristics, even if several volume percents of the organic solvent or the like remains in the TeI₄ film. However, if 10 or more volume percents of the organic solvent remains in the film, there is a high possibility that the characteristics such as the carrier mobility deteriorate, which is not desirable.

As described so far, a semiconductor element of this embodiment has a semiconductor layer formed with TeI₄, and the TeI₄ has a clustering structure. Thus, a semiconductor element having a semiconductor layer that exhibits high carrier mobility and is easy to form can be provided.

Although TFTs have been described as semiconductor elements of this embodiment, the present invention may of course be applied to any semiconductor element (such as a field effect transistor, a diode, or coated wirings) as long as it has the above described semiconductor layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor element comprising:
a semiconductor layer that contains TeI₄ having a clustering structure.

2. The semiconductor element as claimed in claim 1, wherein the TeI₄ has a clustering structure of (TeI₄)ₙ (n≧4).

3. The semiconductor element as claimed in claim 1, wherein the TeI₄ is agglomerated by virtue of intermolecular force.

4. The semiconductor element as claimed in claim 1, wherein the semiconductor layer is an active layer for TFT.

5. The semiconductor element as claimed in claim 2, wherein the TeI₄ is agglomerated by virtue of intermolecular force.

6. The semiconductor element as claimed in claim 2, wherein the semiconductor layer is an active layer for TFT.

7. A method of manufacturing a semiconductor element, comprising:
solving TeI₄ with an organic solvent; and
applying a solution containing the TeI₄ solved with the organic solvent to a substrate to form a semiconductor layer containing the TeI₄.

8. The method as claimed in claim 7, wherein the applying of the solution is performed by one of a casting method, a spin coating method, and an inkjet method.

9. The method as claimed in claim 7, wherein the TeI₄ has a clustering structure of (TeI₄)ₙ (n≧4).

10. The method as claimed in claim 7, wherein the TeI₄ is agglomerated by virtue of intermolecular force.

11. The method as claimed in claim 7, wherein the semiconductor layer is an active layer for TFT.

12. The method as claimed in claim 9, wherein the TeI₄ is agglomerated by virtue of intermolecular force.

13. The method as claimed in claim 9, wherein the semiconductor layer is an active layer for TFT.
